(19) United States
(12) Patent Application Publication
(10) Pub. No.: US 2006/0002443 A1
(43) Pub. Date: Jan. 5, 2006

(54) Multimode external cavity semiconductor lasers

(76) Inventors: Gennady Farber, Los Altos, CA (US); Hai-Feng Liu, Cupertino, CA (US)

Correspondence Address: MARSHALL, GERSTEIN & BORUN LLP, 233 S. WACKER DRIVE, SUITE 6300, SEARS TOWER, CHICAGO, IL, 60606, US

(21) Appl. No.: 10/883,423

(22) Filed: Jun. 30, 2004

(51) Int. Cl. H01S 5/00; H01S 3/08; H01S 3/10

(52) U.S. Cl. 372/50.1; 372/20; 372/92

(57) ABSTRACT

External cavity laser devices provide multimode laser operation by using a wavelength selective element that produces a spectral width profile able to support multiple longitudinal laser modes. The spectral width profile, for example, may have a substantially flat response across multiple longitudinal laser modes, such that no single mode predominates. The wavelength selective elements may be gratings written in waveguides, where the grating's bandwidth as well as the laser cavity length set the number of supported longitudinal laser modes. In some examples, a tuning element may be used to adjust device operation. In further examples, a laser gain region and the wavelength selective element may be angled with respect to adjacent coupling facets to reduce reflection losses within the laser cavity.

### FIELD OF THE INVENTION

The present invention generally relates to laser devices such as those that may be employed in networking applications and, more particularly, to semiconductor lasers.

### BACKGROUND OF THE INVENTION

Light sources such as lasers or light emitting diodes are used to produce modulated signals that carry information across optical networks. Generally, these light sources should enjoy stable operation, consistently providing signals at predetermined frequencies and with little loss. Such stable operation is increasingly more important in high-demand optical networks, such as Wavelength Division-Multiplexing (WDM) and Dense Wavelength-Division Multiplexing (DWDM) systems, where numerous data streams may be propagating simultaneously. In WDM and DWDM networks, network performance would vary channel to channel, data stream to data stream, if consistent laser operating characteristics were not maintained.

Laser diodes, a common type of network laser source, come in three different forms, and the specific form used is often dictated by the requirements of the network. Configurations include distributed feedback lasers (DFBs), Fabry-Perot lasers, and external cavity lasers (ECLs). Each configuration is capable of producing relatively narrow-bandwidth laser energy, via the use of different types of highly reflective laser cavities that limit the laser energy's. Low-cost Fabry-Perot lasers are often used for short-distance low data rate (<2.5 Gb/s) transmissions, whereas DFB lasers are often used in high data rate transmission over longer distances. In other applications, especially where external modulators impart signal data, ECLs are used. Additional factors affecting laser configuration include whether a laser cooling system is to be used to reduce noise and output frequency fluctuations. ECLs, for example, are commonly used in cooled environments, principally because ECLs produce higher output energies, but also because network designers prefer to have more stable light sources with narrower spectral widths. In contrast, where a cooled environment is not needed, FP or DFB lasers are typically used.

Although there have been a number of attempts to use ECLs to replace costly DFB lasers, there are some fundamental issues that limit ECL applications for un-cooled environments. In the ECL, the resonant cavity is formed by an external element, usually a grating that provides wavelength selection. These ECL's, however, are susceptible to mode hopping, a phenomena that can occur with changes in temperature or injection/drive current, as well as with parasitic reflections. In optical networks, mode hopping can be quite problematic and induce bit error rate degradation in the system. ECLs, for example, use narrow-bandwidth reflective elements that only allow for one dominant laser mode. If a laser source is producing a laser signal operating at that mode, then the laser signal experiences minimal loss. Yet, if operating conditions in the laser change, the laser's lasing wavelength may hop to another mode. This mode could be close to the dominant lasing mode, but transition from one mode to another mode results in sudden change in optical power. As a result, even small fluctuations in operation conditions can result in a laser signal intensity dropping off dramatically, due to mode hopping.

Some have proposed techniques for reducing mode hopping in laser sources, but the proposals have been limited to single-mode devices that do not avoid the inherent modal dependence on output intensity. For example, thermal compensators, such as a silicone layer, could be used in an external laser cavity to counteract the effects of temperature change on the cavity length. The compensator could attempt to produce an equal and opposite temperature effect on the laser device. Yet, the technique is only able to quell mode hopping over a limited range of temperatures and, thus, not well suited for widespread commercial use. Further, while conceptually thermal compensators should reduce the affects of temperature changes, in fact, the thermal-optic coefficients of the compensating materials are non-linear, meaning that it is very difficult to achieve total thermal compensation over an entire operational temperature window of an un-cooled device. Plus, these systems merely attempt to prevent mode hopping. If mode hopping ever does occur, there will still be a dramatic drop off in signal intensity. In another example, an un-cooled ECL using a fiber Bragg grating with a moderately-widened bandwidth larger than the longitudinal mode spacing has been proposed. But the system, as with those described above, is a single-mode system that would exhibit sizable and undesirable model dependence in signal intensity.

### BRIEF DESCRIPTION OF THE DRAWINGS

FIG. 1 illustrates a perspective view of a multimode laser apparatus including a laser source coupled to a wavelength selective element.

FIG. 2 is a side illustration of the apparatus of FIG. 1.

FIG. 3 is a top view of an example laser apparatus having an angled facet to reduce reflection losses with a laser device.

FIG. 4 is a spectral plot of multiple longitudinal laser modes and grating profile with bandwidth for a laser apparatus in accordance with the example of FIGS. 1-3.

FIG. 5 illustrates another example multimode laser apparatus including a tuning element.

FIG. 6 illustrates an example wavelength selective element bandwidth profile for a laser apparatus at different temperature operating conditions.

FIG. 7 illustrates a block diagram of a transceiver including a multimode laser apparatus, in an example.

FIG. 8 illustrates a multi-channel, multimode laser apparatus that may be used in a wavelength division multiplexed system, in an example.

### DETAILED DESCRIPTION

Although a number of devices are described with reference to illustrated examples, the disclosure is not limited to these examples. Thus, although external cavity lasers are described with an external grating element as a wavelength selective device, persons of ordinary skill in the art will recognize that other wavelength selective devices may be used, including highly reflective wavelength filters.

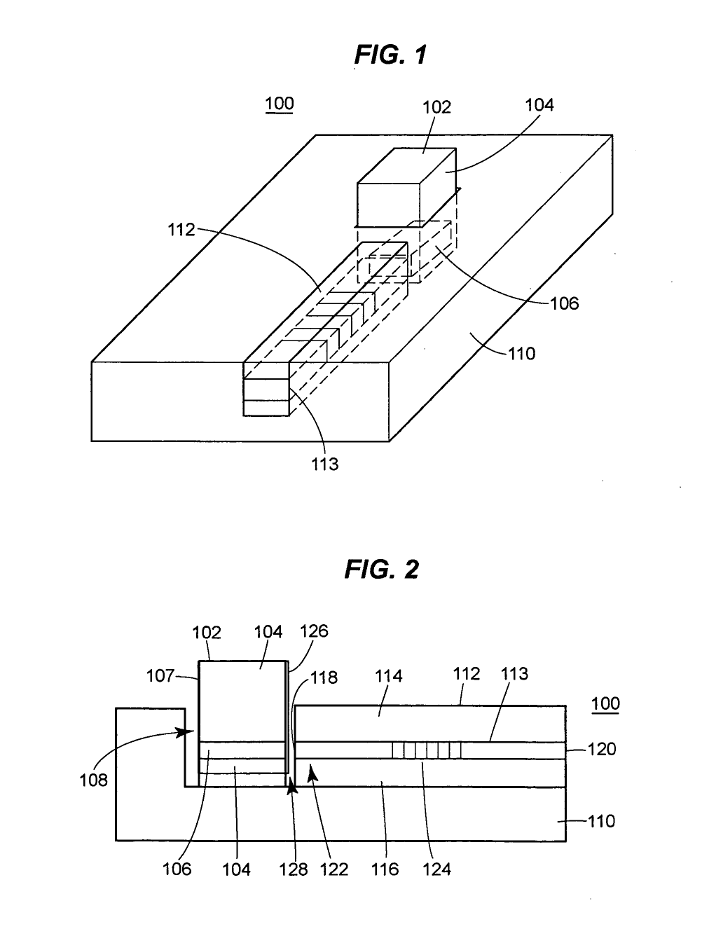

FIG. 1 illustrates an example laser apparatus 100 that has a grating profile of sufficient bandwidth (or spectral cavity profile) to support multiple longitudinal laser modes. The apparatus 100 is in an external cavity laser configuration and includes a laser source 102, e.g., a side-emitting laser diode having a cladding region 104 surrounding laser gain region, or core, 106. This laser source 102 is shown by way of example. The apparatus 100 may use another type of laser source, e.g., a vertical cavity surface emitting laser, fiber laser, or optical amplifier. The laser source 102 may be a III-V semiconductor laser providing laser energy at any output frequency, of which the known telecommunication frequencies band centered at 850 nm, 1310 nm, and 1550 nm are examples. In very short reach (VSR) applications, like those of an enterprise space, campus local area networks (LANs), and storage area networks (SANS), the laser source 102 may be an 850 nm GaAs/AIGaAs diode laser, for example, although any suitable light emitting material may be used. Typical operating parameters for VSRs include 10 Gb/s data transmission rates on 25-300 m fibers, including multi-mode fibers (MMFs)—although, single mode fibers (SMFs) may be used as well. The laser source 102 may alternatively provide output at the 1310 nm or 1550 nm telecommunication bands, for example, in wide area networks (e.g., longer reach, 10 km links) and metro area networks (e.g., extended reach, 10 km links). The output wavelength of the laser source 102 may be matched to reduce propagation loss and chromatic dispersion within the apparatus 100 and optical fibers coupled thereto, for example, by using a laser source producing a wavelength larger than approximately 1.1 μm, where silicon waveguides exhibit relatively low optical absorption. In some examples, the lasing material may be a non-linear material.

By way of example, the gain region 106 may be formed of a lasing material that has been epitaxially grown in the cladding layer 104, or the gain region 106 may be formed via doping/implantation process to create the higher index gain region. As a laser diode chip, the laser source 102 may be batch fabricated using Silicon wafer technology and diced to produce large numbers of such sources.

The laser source 102 may include a first cavity reflector 107, which may be as cleaved or coated with a dielectric, for example. In the illustrated example, the reflector 107 may reflect most of the laser energy within the laser source 102. The laser source 102 may be disposed within a recess or cavity 108 formed in a substrate 110, such as a semiconductor substrate or Silicon optical bench (SiOB) exposed to a pattern-and-etch lithography process. The recess 108 is positioned and sized to align the gain region 106 with a wavelength selective element, e.g., an external reflector element 112 for low-loss coupling between the two. By way of example, the laser source 102 may be bonded, glued, or fastened into the recess 108.

In the illustrated example, the external reflector element 112 includes a waveguide core 113 formed within the substrate 110, for example, via a Silicon on insulator (SOI) process, other epitaxial growth process, and/or a doping/implantation process. Alternate to these integrally formed techniques, a separately-formed waveguide may be mounted to the substrate 110, for example by mounting a single-mode, multi-mode, or plastic optical fiber in a substrate groove, such as a V-groove or U-groove. Although not shown, coupling optics may be used between the laser source 102 and the element 112 to prevent unwanted coupling loss.

As illustrated in FIG. 2, the waveguide core 113 may extend between two cladding regions, 114 and 116, that may be formed of the same cladding material and formed in the substrate 110, in an example. The waveguide core 113 has an input end 118 adjacent and in communication with the laser source 102 and an exit end 120 through which laser energy from the laser source 102 is provided.

The element 112 forms part of a laser cavity 122 that has a longitudinal cavity mode profile that supports a plurality of longitudinal laser modes, as discussed in further detail below. To provide high reflectivity and a sufficiently broad longitudinal-laser bandwidth profile, the element 112 includes a highly-reflective, partially transmissive grating 124. The grating 124 may by 70%-90% reflective, for example, and forms a second laser cavity reflector for laser cavity 122.

The grating 124 may be formed in the waveguide core 113 using a photomasking, laser writing, etching, diamond cutting, or silicon doping, techniques. The grating 124 may be formed of silica, a polymer material, or a IIIN semiconductor structure. In an example, the grating 124 may be written by irradiating the substrate 110 with an ArF excimer laser operating at 193 nm. Such techniques may allow for grating line-width and spacing accuracy in the sub 1 nm range. Additionally, exposure saturation techniques may be used to affect the depth and index profile of the grating lines, for example, creating grating lines with uniform indexes of refraction across the entire line.

In another example, etching deep trenches into a SOI wafer/waveguide and filing these trenches with a poly-silicon, annealed to reduce lattice mismatch and loss, may be used to fabricate the grating. The poly-silicon may be chemically or mechanically polished to obtain a planar surface with the top of the element 112, before the cladding layer or the remainder of the cladding layer is deposited. With this latter technique, narrow reflection bandwidths of approximately 1 nm or below may be achieved, for example, between 0.5 and 0.3 nm. The grating 124 is not limited to these fabrication techniques, however, nor is the grating 124 limited to specific reflection bandwidths, as the bandwidth may depend upon the desired conditions of the laser apparatus.

In the illustrated example, the grating 124 has a relatively narrow reflection bandwidth, but instead of producing a laser with single-mode operation where the side modes adjacent a principle longitudinal laser mode are suppressed, the grating bandwidth is large enough to reflect a number of longitudinal modes and, therefore, large enough to create a spectral cavity width that supports multiple laser modes. As explained in further detail below, the grating bandwidth may support 3 to 8 longitudinal modes, for example. The grating bandwidth may be adjusted by affecting the optical path length of the grating. Further, even though the grating bandwidth is large enough to support multiple longitudinal modes, the wavelength selective element 112 may also meet accepted industry standards for channel spacing and wavelength stability in systems such as WDM and DWDM systems operating over the C-band wavelength region.

As illustrated in FIG. 2, intra-cavity reflection losses within the laser source 102 may be reduced by an antireflection coating layer 126 formed on the laser source 102. Additionally, an anti-reflection coating layer may be formed at the entrance face 118 of the element 112 to reduce reflection back into the laser cavity or back into the element 112. Or an air gap region 128 extending between the laser source 102 and element 112 may be filled with an index of refraction matching material. With an antireflection coating or index-matching material, intra-cavity reflections may be reduced.

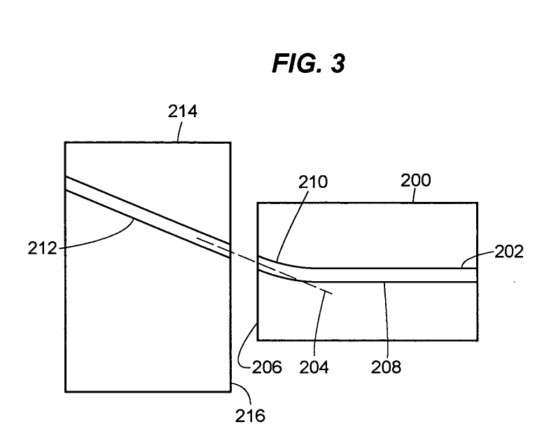

Additionally, to reduce intra-cavity reflection losses, the gain region 106 may be curved or angled from an output face surface normal to form an angled-facet output face. An example configuration is illustrated in FIG. 3, which shows an example laser source 200 with a gain region 202 defining an axis 204 that forms an acute angle with a surface normal on exit end 206. Because light within the gain region 202 is incident on the exit end 206 at a non-normal angle of incidence, reflection back into the cavity is reduced.

In the illustrated example, the gain region 202 has a linear portion 208 and a curved portion 210 having a radius of curvature sufficiently large to prevent bending loss in the gain region 202. As illustrated, the curved portion 210 aligns with a waveguide 212 of an external wavelength selective element 214 that also has an acute-angle entrance face 216. Angles of less than 10° from surface normal may be used to decrease reflectively at an entrance/exit face. For example, an 8° facet angle could result in less than 10⁻³ reflection at the facet, depending on the materials used. The reflection loss may be reduced even further by using an anti-reflection coating, as described above. Nevertheless, the low-loss configuration illustrated in FIG. 3 is provided by way of example, and the illustrated enhancements are optional. Furthermore, coupling enhancements may also be used, such as forming a tapered waveguide portion of the element 212 to match the size of the gain region 202 or the light beam emanating therefrom.

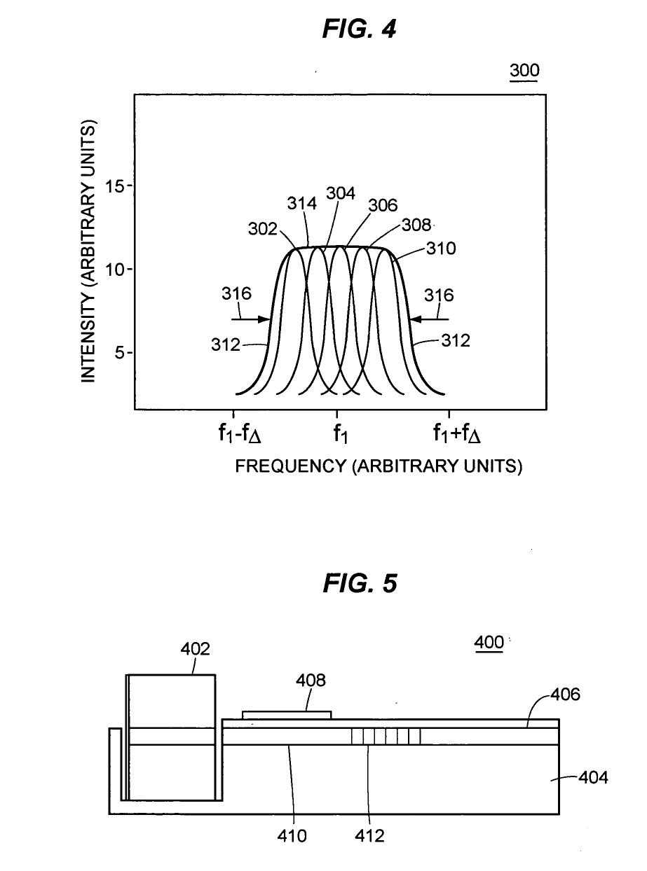

An example plot 300 of longitudinal laser modes and grating profile of an example bandwidth is shown in FIG. 4. Pluralities of longitudinal laser modes (302, 304, 306, 308, and 310) that may propagate within a laser apparatus are illustrated. The mode 306 may be considered a principle mode, with modes 302, 304, 308, and 310 considered side modes, although these designations are arbitrary. Numerous other side modes are theoretically available based on the dimensions of the laser cavity extending from a first reflector to a second reflector, such as the wavelength selective device. The modes 302, 304, 306, 308, and 310, however, are the only supported modes in the illustrated example, because a grating profile with bandwidth 312 of the laser cavity envelopes these modes.

The grating profile 312 has a substantially flat profile (plateau) 314, over which small reflection differences occur between the longitudinal modes 302, 304, 306, 308, and 310. The plateau 314 is smaller than a full-width half-maximum (FWHM) 316, but large enough to support each of the modes 302, 304, 306, 308, and 310. As a result of the substantial flatness of the plateau 314 and thus the substantial flatness of the grating profile 312, the grating profile 312 is such that no one longitudinal laser mode dominant. That is, substantially all modes 302-310 will see the same profile maximum value, and thus mode hopping between longitudinal laser modes or movements of a mode (for example, via thermally-induced fluctuations) will not result in a substantial reduction in intensity of the output signal. Thus, the average power of a signal may be stable, even under temperature or refractive index changes.

Merely by way of example, a substantially flat grating profile may be chosen with a plateau that produces approximately 10% or less grating reflectivity difference among the supported modes. The reflectivity difference between modes may reflect an intensity difference between light energy produced by the laser at the modes. As the reflectivity difference between modes is lowered, the output intensity for these modes will approach one another, becoming substantially the same for very low reflectivities. In some examples, approximately 5% or less reflectivity difference may be desired. Gratings may be chosen, such that the grating profile exhibits approximately 1% reflectivity difference between the support modes, for example.

The spectral width of the cavity laser is determined by the linewidth of the laser source and the profile of the wavelength selective element used therein. In the example of a grating as the wavelength selective element, the grating period, length, depth (i.e., shallowness of grating lines), and material may all be adjusted to create a grating profile with a bandwidth that results in a particular spectral width for the cavity laser. Further, the amount of saturation achieved by the source used to form the gratirig lines (e.g., excimer laser saturation) may affect the flatness of the grating profile and, thus, the flatness of the spectral widths bandwidth plateau.

Thus, in an example, to achieve spectral cavity widths of substantially flat profiles, the grating profile should be substantially flat as well, for example producing approximately 10% or less reflectivity difference among the supported longitudinal modes, e.g., approximately 1%-5%. These percentages are examples though, as the substantially flat grating profiles may be set to any useful tolerances.

By way of example, substantially flat grating profiles (or plateau widths) below 1 nm may be used. In some examples, a 0.3 or 0.4 nm grating bandwidth plateau may be used for 0.08 nm longitudinal mode spacings, with an overall cavity length of approximately 12 mm. In other examples, 8 supported modes may be formed by using a grating with profile of approximately 0.5 nm with an approximately 0.06 nm (i.e., 7.5 GHz) mode spacing. For an approximately 0.08 nm (i.e., 10 GHz) mode spacing, then six modes may be supported over 0.5 nm. Fora 0.16 nm (i.e., 20 GHz) mode spacing, three modes may be supported. These examples illustrate longitudinal mode spacings of below approximately 0.2 nm with substantially flat grating profiles across a bandwidth plateau of 1 nm and below. These values are provided by way of example, however.

In some examples, narrower spectral widths or grating profiles may be used for longer distance transmission systems to reduce dispersion effects. Generally, however, the grating parameters may be adjusted to create a grating profile that results in a spectral width that coincides with the distance requirement for the transmission system.

As the grating profile can be narrower than standard Fabry Perot lasers, the performance of laser devices in an external cavity laser configuration using a grating as the wavelength selective element may be improved. Further, temperature stability may be improved in comparison with Fabry Perot lasers, as the lasing wavelengths are defined by the grating residing in the optical waveguide. With a silicon-based waveguide for the wavelength selective element, for example, the wavelength drift may be on the order of 0.01 nm/° C. Further, the techniques may be used over much larger temperature ranges, because the techniques are substantially independent of operating temperature.

In the illustrated example, a substantially flat grating profile is wide enough to support five supported longitudinal laser modes, but fewer or additional numbers of modes may be supported. For example, three to eight or more modes may be simultaneously supported by the laser apparatus, where fewer supported modes means that the device will be more susceptible to mode hoping or mode shift.

In an implementation, a grating profile may be chosen to have a certain size, for example, by setting the number of lines in the grating to an amount corresponding to an identified bandwidth. Next, the number of modes that are to be supported for the device may be chosen based on the sensitivity or responsiveness of the laser device to fluctuations in the longitudinal mode. If the laser apparatus is to be more tolerant to mode hopping, then a few number of longitudinal modes may be selected. After the number of supported modes is selected, the cavity length of the laser apparatus may be determined and the length from the first cavity reflector to the second set. In the example of a grating as the second cavity reflector, a mid point within the grating may be referenced for setting cavity length. The cavity length will determine the spacing between the longitudinal modes.

Numerous examples are described above; however, it should be appreciated that these examples may be modified or changed. For example, the structures described may be replaced with other structures. The wavelength selective element, which is a waveguide grating, in some examples, may be replaced with any suitable wavelength selective element, for example, a wavelength filter, such as a thin film, etalon or Fabry Perot filter. The element should have a substantially flat bandwidth so that no dominant mode among the plurality of supported modes is created; although, this need not be the case, as one or more modes may experience higher reflectivities (or lower loss) than another mode and still be a supported mode in the device.

Furthermore, although the examples are described with reference to a grating of a given frequency response, a tunable wavelength selective element may be used, such as a tunable grating element or tunable waveguide. FIG. 5 illustrates an example laser apparatus 400 including a laser diode 402 disposed in a substrate 404 and adjacent a wavelength selective element 406. A tuning element 408, e.g., an electrode, is positioned over a waveguide segment 410 of the wavelength selective element 406. The waveguide segment 410 may be formed of an electrically-responsive material such as LiNbO₃ (lithium niobate) or any electro-optical material, which has an index of refraction that changes under application of an electric field. Thus, applying a voltage to the electrode 408 will change the laser cavity length of the laser apparatus 400, thereby changing the spacing between longitudinal laser modes, and if the spacing change is large enough, changing the number of supported longitudinal laser modes. Alternatively, the bandwidth of the wavelength selective element may be tuned, for example, by positioning the electrode 408 over a grating 412 in the wavelength selective element 406, such that the bandwidth is altered in response to application of an electric field.

In another alternative, instead of an electrode, a heating or thermal element may be positioned adjacent a waveguide portion, grating portion, or both of a wavelength selective element to induce an index of refraction change to change the mode spacing or bandwidth. Alternatively, the substrate of the apparatus may be mounted on a thermoelectric material that is capable of inducing temperature changes. In these examples, the wavelength selective element may be formed of a polymer having a temperature dependent index of refraction. The thermo-optic effect, for example, may be used to tune the grating by heating it, thereby tuning the frequency of the laser energy, that is, the centermost point on the grating profile and thus the centermost frequency of the spectral width of the cavity laser. Example responsiveness is approximately 12.5 nm/100° C. In another example, tuning may be achieved by mechanical techniques, such as strain/stretch. For example, mechanically stretching or compressing a fiber grating may induce a change in the propagation properties of a laser device to change the number of supported longitudinal modes.

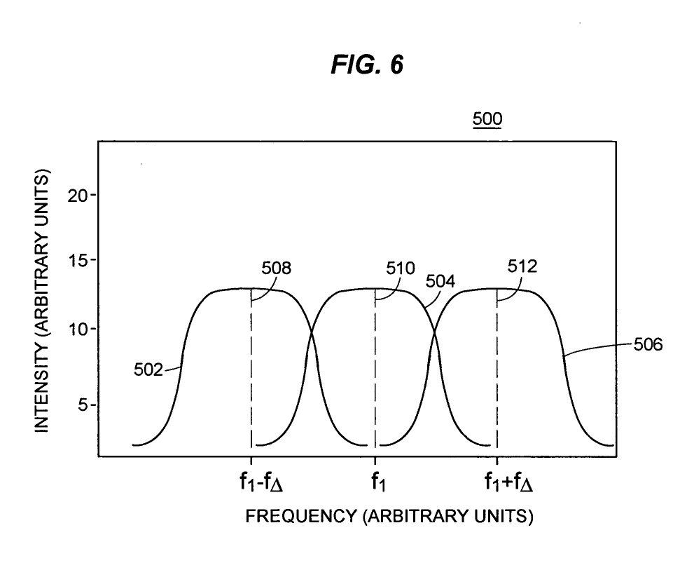

FIG. 6 provides a plot 500 of the variation in bandwidth profile for a laser apparatus at different tuned temperatures for a wavelength selective element. Curves 502, 504, and 506 represent different wavelength selective element bandwidths at three different temperatures that are offset from one another, i.e., the curves 500, 502, and 504 have center wavelengths 508, 510, and 512, respectively. These bandwidths 500, 502, and 504 will determine the spectral width of the laser and, thus, the number of supported modes. In this way, a tuning element may be used to tune the center wavelength of a bandwidth profile to coincide with a particular output frequency. Such tuning may be useful in DWDM systems that include a number of laser signal channels, each operating at a different channel frequency, such that the wavelength selective element for a particular channel is tuned to have a center frequency that corresponds to the channel frequency.

Other techniques for tuning either the longitudinal mode spacing or wavelength selective element bandwidth may be used. For example, either the first or second laser cavity reflector may be an external reflector mounted to a movable translation stage, thermally-, electrically-, or mechanically-controlled. That is, the laser source and the wavelength selective element may be movable relative to one another.

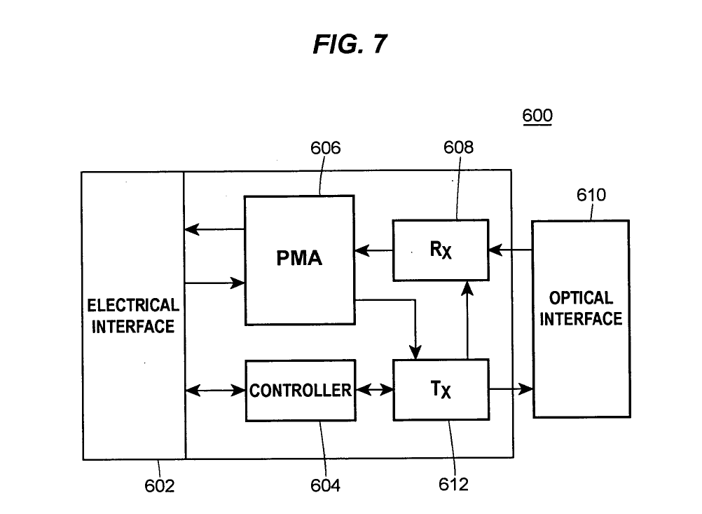

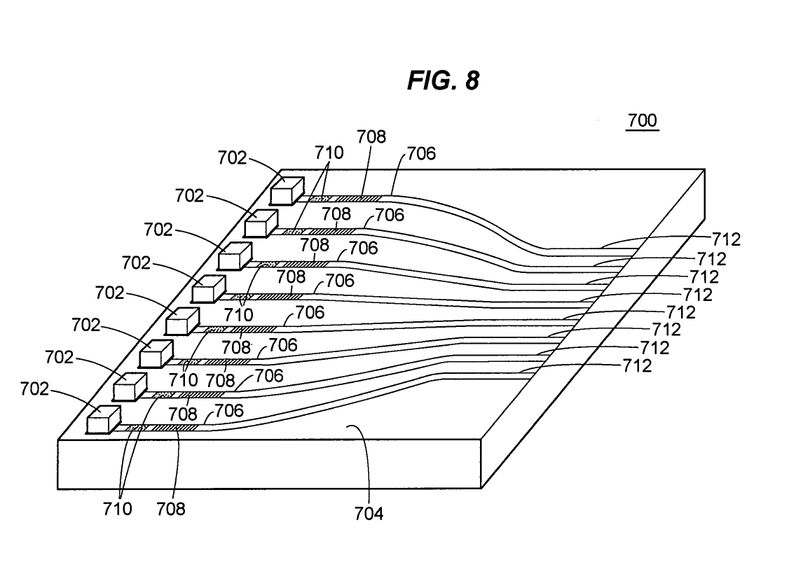

The laser devices described may be used in various applications, including transponders and transceivers, such as those used in local area networks, wide area networks, and metro area networks. An example 10 Gb/s optical transceiver 600 is illustrated in FIG. 7. An electrical interface 602 provides input/output data transfer with a host card or host processor environment. DC power, ground connections, various clocking channels, control signals, and monitoring channels may be coupled to the transceiver 600 via the electrical interface. The interface may take the form of a socket pluggable into a host board, for example. The width of the data bus provided by the interface 602 may vary depending on the application, as well as the bit rate through the interface 602.

The transceiver 600 further includes a control system, for example a microcontroller 604. In the illustrated example, a physical medium attachment 606 (PMA) is provided and provides the electrical functionality of the transceiver 600. For example, the PMA 606 may provide clock multiplier/multiplexer (MUX/CMU) and/or clock data recovery/demultiplexer (CDR/DeMUX).

The transceiver 600 also includes an optical receiver 608, which may represent an array of optical receivers. Examples include receivers for 10 Gb/s links based on either InP-based or GaAs-based PIN photodiodes or avalanche photodiodes. The receiver 608 converts received optical energy from an optical interface 610 into ah electrical signal provided to the microcontroller 604 and the PMA 606. Although not shown, various circuit elements may be integrated into the optical receiver 608, such as a transimpedance amplifier and limiting amplifier to provide high gain and high sensitivity response. The transceiver 600 also includes a transmitter 612, or array of transmitters, that includes an external cavity laser source such as those described hereinabove.

The transceiver 600 is illustrated in block form. In packaged form, the transceiver 600 may include cooled or un-cooled “butterfly” packages and TO-can style packages.

The laser sources described herein may be combined in an array, or like fashion, to produce multi-channel laser devices. Identical laser diode chips, for example, may be batched fabricated and then diced from a processed wafer sample to be combined into a device operating at different wavelengths. WDM or DWDM transceivers are examples.

An example multi-channel device 700 is shown in FIG. 8. The device 700 includes an array of laser diodes 702, each disposed within one of an array of recesses within a substrate 704. As with similar laser sources described above, the laser diodes have gain regions aligned for coupling energy into a wavelength selective element 706, for example, one of a plurality of waveguides having a grating 708 positioned therein. Each laser diode 702 and wavelength selective element 706 pair forms a different laser source associated with a different channel, and each laser source includes one tuning element 710 that may be used to tune the particular laser source to a particular center frequency, such that each laser source may operate at a different laser wavelength. Each wavelength selective element 706 is coupled to an output waveguide 712 which may be coupled to an optical multiplexer or another type of optical interface, such as an optical modulation stage.

Although the devices described are described in the context of laser apparatuses providing a continuous wave output, the devices may be used to produce information carrying modulated optical signals. For example, the laser apparatuses may have output waveguides coupled to optical modulators, such as electro-optical crystals formed of LiNbO₃ or III-V semiconductor compounds, including multiple quantum well structures. Waveguides may be coupled to Mach-Zehnder interferometer (MZI) modulators including two waveguide arms, each with a section for converting an applied voltage into a propagation delay between the two arms, thus modulating an incident laser signal.

Although certain apparatus constructed in accordance with the teachings of the invention have been described herein, the scope of coverage of this patent is not limited thereto. On the contrary, this patent covers all embodiments of the teachings of the invention fairly falling within the scope of the appended claims either literally or under the doctrine of equivalence.

What is claimed is:

1. A laser apparatus comprising:
a laser source;
a first reflector disposed to reflect laser energy from a first end of the laser source; and
a wavelength selective element disposed to reflect laser energy from a second end of the laser source to form a laser cavity with the first reflector, the wavelength selective element having a substantially flat profile over at least two longitudinal laser modes of the laser cavity.

2. The laser apparatus of claim 1, wherein the wavelength selective element is positioned such that an output laser energy at any of the at least two longitudinal modes has an intensity that is substantially independent of the longitudinal laser mode.

3. The laser apparatus of claim 1, wherein the laser source, first reflector, and wavelength selective element are in an external cavity laser configuration, with the wavelength selective element disposed externally to the laser source.

4. The laser apparatus of claim 1, wherein the wavelength selective element comprises a grating having a grating profile that is substantially flat over the at least two longitudinal laser modes.

5. The laser apparatus of claim 4, wherein the grating profile is substantially flat over between three and ten longitudinal laser modes.

6. The laser apparatus of claim 1, wherein the substantially flat profile has a reflectivity difference among the at least two longitudinal modes of approximately 10% or below.

7. The laser apparatus of claim 6, wherein the reflectivity difference is approximately 5% or below.

8. The laser apparatus of claim 1, wherein a longitudinal laser mode spacing is approximately 0.2 nm or below and the substantially flat profile is approximately 1 nm or below.

9. The laser apparatus of claim 1, further comprising an anti-reflection material disposed to reduce intra-cavity reflections.

10. The laser apparatus of claim 1, wherein the laser source is a laser diode that comprises an acute angled-facet output face.

11. The laser apparatus of claim 10, wherein the wavelength selective device comprises a waveguide aligned with a laser source axis at the acute angled-facet output face.

12. The laser apparatus of claim 1, further comprising a tuning element disposed adjacent the wavelength selective device to change a center frequency of the laser apparatus.

13. A multi-channel laser apparatus comprising:
at least two laser devices, each laser device comprising:
a laser source;
a first reflector disposed to reflect laser energy from a first end of the laser source; and
a wavelength selective element disposed to reflect laser energy from a second end of the laser source to form a laser cavity with the first reflector, the wavelength selective element having a substantially flat profile over at least two longitudinal laser modes of the laser cavity.

14. The multi-channel laser apparatus of claim 13, wherein the wavelength selective element is positioned such that an output laser energy at any of the at least two longitudinal laser modes has an intensity that is substantially independent of the longitudinal laser mode.

15. The multi-channel laser apparatus of claim 13, further comprising at least two output waveguides, each of which is coupled to one of the at least two laser devices.

16. The multi-channel laser apparatus of claim 13, wherein an output laser energy for one of the at least two laser devices has a first center frequency, and an output laser energy for another of the at least two laser devices has a second center frequency different than the first center frequency.

17. The multi-channel laser apparatus of claim 16, further comprising at least one tuning element disposed to tune the output laser energy for the one of the at least two laser devices to the first center frequency.

18. The multi-channel laser apparatus of claim 13, wherein the substantially flat profile has a reflectivity difference among the at least two longitudinal modes of approximately 10% or below.

19. The multi-channel laser apparatus of claim 18, wherein the reflectivity difference is approximately 5% or below.

20. An optical transceiver comprising:
an optical receiver for receiving first optical signals; and
an optical transmitter for transmitting second optical signals, wherein the optical transmitter comprises:
a laser source;
a first reflector disposed to reflect laser energy from a first end of the laser source; and
a wavelength selective element disposed to reflect the laser energy from a second end of the laser source to form a laser cavity with the first reflector, the wavelength selective element having a substantially flat profile over at least two longitudinal laser modes of the laser cavity.

21. The optical transceiver of claim 20, wherein the wavelength selective element is positioned such that an output laser energy at any of the at least two longitudinal laser modes has an intensity that is substantially independent of the longitudinal laser mode.

22. The optical transceiver of claim 20, further comprising:
an electrical interface coupled to the controller; and
physical medium attachment coupled to the electrical interface and the controller.

23. The optical transceiver of claim 20, wherein the controller is a microprocessor.

24. The optical transceiver of claim 20, wherein the laser source, first reflector, and wavelength selective element are in an external cavity laser configuration.

25. The optical transceiver of claim 20, wherein the wavelength selective element is a grating having a grating profile that is substantially flat over the at least two longitudinal laser modes.

26. The optical transceiver of claim 20, wherein the substantially flat profile has a reflectivity difference among the at least two longitudinal modes of approximately 5% or below.
